(19) United States
(12) Patent Application Publication
(10) Pub. No.: US 2013/0175563 A1
(43) Pub. Date: Jul. 11, 2013

(54) LED CHIP STRUCTURE, PACKAGING SUBSTRATE, PACKAGE STRUCTURE AND FABRICATION METHOD THEREOF

(71) Applicants: Yuen-Han Wang, Taichung Hsien (TW); Sheng-Li Lu, Taichung Hsien (TW); Kuan-Yu Yang, Taichung Hsien (TW); Hsien-Wen Chen, Taichung Hsien (TW); Jih-Fu Wang, Taichung Hsien (TW)

(72) Inventors: Yuen-Han Wang, Taichung Hsien (TW); Sheng-Li Lu, Taichung Hsien (TW); Kuan-Yu Yang, Taichung Hsien (TW); Hsien-Wen Chen, Taichung Hsien (TW); Jih-Fu Wang, Taichung Hsien (TW)

(73) Assignee: SILICONWARE PRECISION INDUSTRIES CO., LTD., Taichung Hsien (TW)

(21) Appl. No.: 13/584,987

(22) Filed: Aug. 14, 2012

(30) Foreign Application Priority Data
Jan. 5, 2012 (TW) 101100417

(51) Int. Cl. H01L 33/60; H01L 23/498; H01L 33/44

(52) U.S. Cl. 257/98; 438/27; 257/782; 257/E33.061; 257/E33.072; 257/E23.06

(57) ABSTRACT

An LED package structure includes: a substrate having a die attach pad; a first insulating layer formed on the die attach pad and having a plurality of openings; an LED chip having an active surface with a plurality of electrode pads and an inactive surface opposite to the active surface; a second insulating layer formed on the inactive surface and having a plurality of openings, wherein the LED chip is disposed on the substrate with the openings of the second insulating layer corresponding in position to the openings of the first insulating layer; and a plurality of metallic thermal conductive elements formed in the openings of the first insulating layer and the corresponding openings of the second insulating layer, thereby effectively alleviating the conventional problem of thermal stresses induced by a mismatch in CTEs of the LED chip and the substrate.

### BACKGROUND OF THE INVENTION

1. Field of the Invention

The present invention relates to LED (Light Emitting Diode) chip structures, packaging substrates, package structures and fabrication methods thereof, and more particularly, to a wire bonding LED package structure and a fabrication method thereof.

2. Description of Related Art

Compared with conventional light sources, LEDs have advantages of high efficiency, high reliability, long lifetime, low power consumption and short response time, are environment-friendly and do not have idling time. Therefore, the application of LEDs has dramatically expanded in recent years. Particularly, LEDs of different colors have been developed and widely adopted in lighting applications, and conventional cold cathode bulbs, halogen bulbs or incandescent bulbs are being replaced by LEDs so as to meet the energy saving and carbon reducing trend.

However, if the power of an LED is greatly increased, the operating temperature of the LED also increases significantly, thereby adversely affecting the lighting efficiency and the lifetime of the LED. For an LED having poor heat dissipating efficiency, the operating temperature of the LED will increase, thus easily resulting in an increased temperature at the pn junction of the LED. On the other hand, the temperature of the pn junction is inversely proportional to the LED brightness. The higher the temperature, the more the LED brightness attenuates. That is, the lighting efficiency of the LED decreases. Furthermore, if the operating temperature of an LED is continuously maintained below 50, the LED has a lifetime of 20,000 hours. If the operating temperature of the LED increases to 75, the LED only has a lifetime of 10,000 hours. Therefore, the operating temperature plays a key role on the lifetime of the LED. Hence, the heat dissipating efficiency is an important factor to be considered in the design of LEDs.

FIG. 1 shows a cross-sectional view of a conventional LED package structure. Referring to FIG. 1, an adhesive layer 11 is formed on a die attach pad 101 of a metallic packaging substrate 10. The adhesive layer 11 can be made of such as epoxy which contains silver particles with high thermal conductivity. Further, an LED chip 12 is mounted on the adhesive layer 11. In this manner, a large thermal conductive area is provided so as to achieve a preferred heat dissipating effect.

However, since there is a mismatch in CTEs of the LED chip 12 and the packaging substrate 10, when a thermal cycle reliability test is performed on the LED package structure, delaminations can easily occur to the interface between the LED chip 12 and the packaging substrate 10 due to induced thermal stresses.

The present invention is directed to various structures and methods so as to avoid, or at least reduce, the effects of one or more of the problems identified above.

### SUMMARY OF THE INVENTION

Accordingly, the present invention provides an LED chip structure, which comprises: a substrate having an active surface with a plurality of electrode pads and an inactive surface opposite to the active surface; an insulating layer formed on the inactive surface of the substrate and having a plurality of openings; and at least one metallic thermal conductive element formed in the openings of the insulating layer.

The present invention further provides an LED packaging substrate, which comprises: a substrate having a die attach pad formed thereon; an insulating layer formed on the die attach pad and having a plurality openings penetrating therethrough; and at least one second metallic thermal conductive element formed in the openings of the insulating layer.

The present invention further provides an LED package structure, which comprises: a substrate having a die attach pad; a first insulating layer formed on the die attach pad and having a plurality of openings; an LED chip having an active surface with a plurality of electrode pads and an inactive surface opposite to the active surface; a second insulating layer formed on the inactive surface of the LED chip and having a plurality of openings, wherein the LED chip is disposed on the substrate with the openings of the second insulating layer corresponding in position to the openings of the first insulating layer; and at least one metallic thermal conductive element formed in the openings of the first insulating layer and the corresponding openings of the second insulating layer.

The present invention further provides a fabrication method of an LED package structure, which comprises: providing a substrate having a die attach pad and a first insulating layer formed on the die attach pad, wherein the first insulating layer has a plurality of openings; and mounting an LED chip on the substrate through a plurality of metallic thermal conductive elements, wherein the LED chip has an active surface with a plurality of electrode pads and an inactive surface opposite to the active surface, and a second insulating layer is formed on the inactive surface of the LED chip and has a plurality of openings corresponding in position to the openings of the first insulating layer so as for the metallic thermal conductive elements to be formed in the openings of the first insulating layer and the corresponding openings of the second insulating layer.

Therefore, by mounting an LED chip on the die attach pad of an LED packaging substrate through a plurality of array-arranged thermal conductive elements, the present invention effectively alleviates the problem of thermal stresses induced by a mismatch in CTEs of the LED chip and the packaging substrate without greatly affecting the heat dissipating capability of the LED package structure, thus improving the reliability of the overall LED package structure.

### BRIEF DESCRIPTION OF DRAWINGS

FIG. 1 is a schematic cross-sectional view showing a conventional LED package structure;

FIGS. 2A to 2G are schematic cross-sectional views showing an LED package structure and a fabrication method thereof according to a first embodiment of the present invention, wherein FIGS. 2A-1, 2A-2 and 2A-3 are bottom views showing different embodiments of FIG. 2A; and

FIGS. 3A to 3G are schematic cross-sectional views showing an LED package structure and a fabrication method thereof according to a second embodiment of the present invention.

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modification and variations can be made without departing from the spirit of the present invention. Further, terms such as “one”, “on”, “top”, “bottom” etc. are merely for illustrative purpose and should not be construed to limit the scope of the present invention.

### First Embodiment

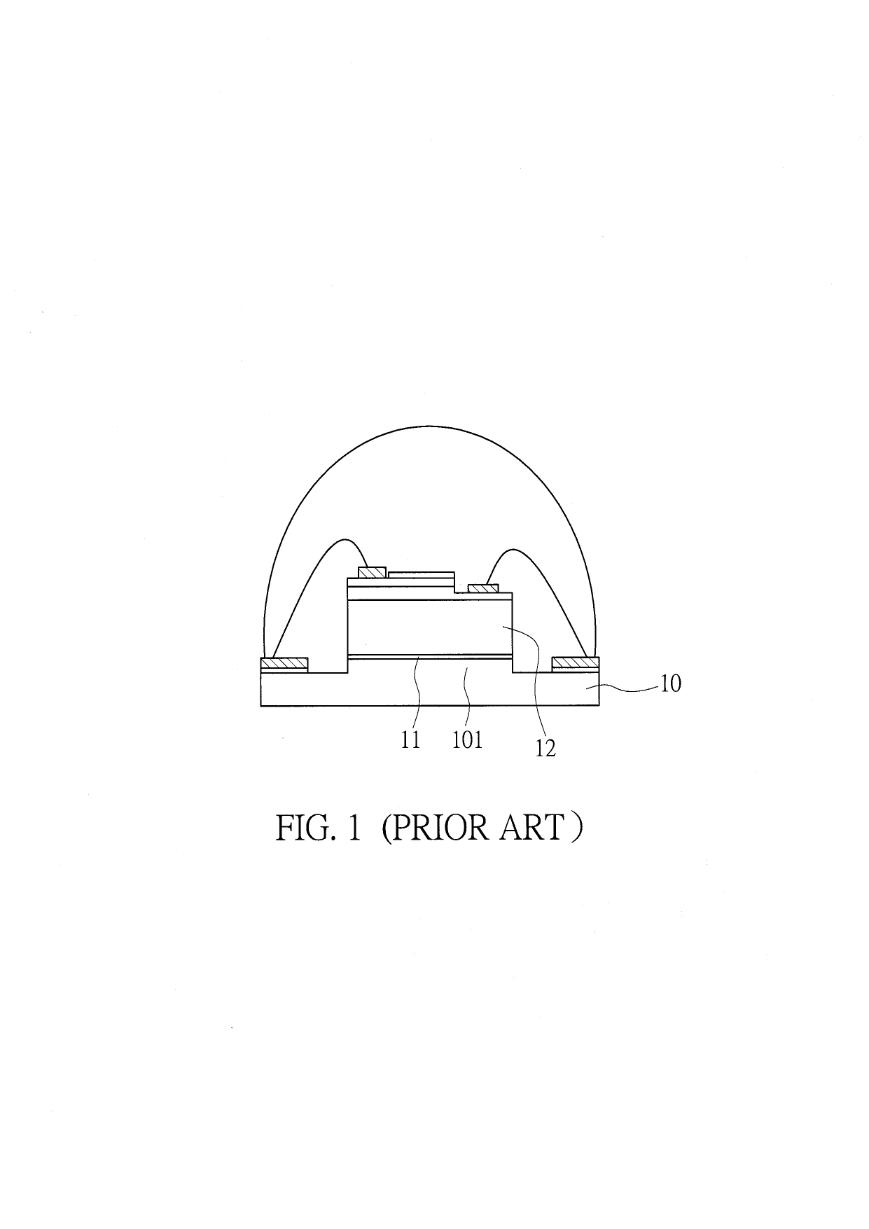

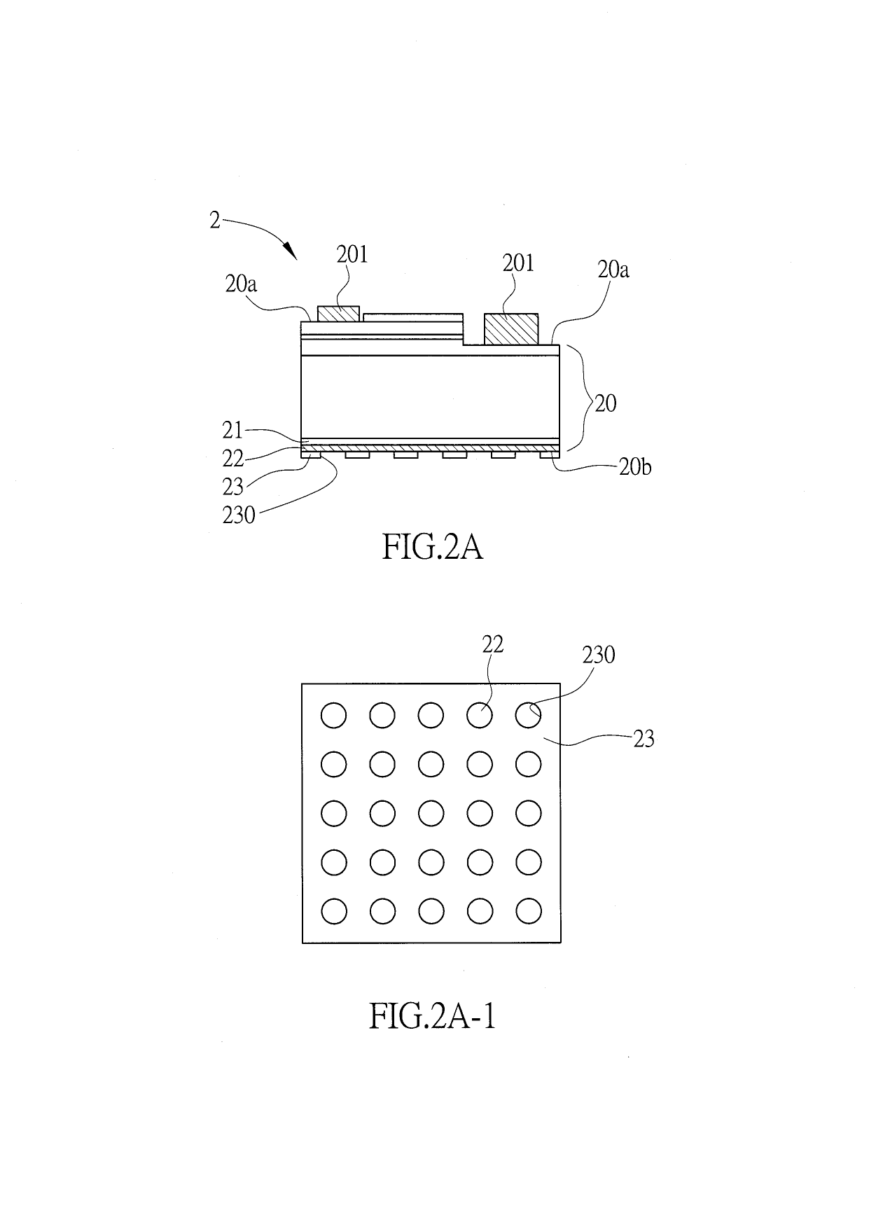

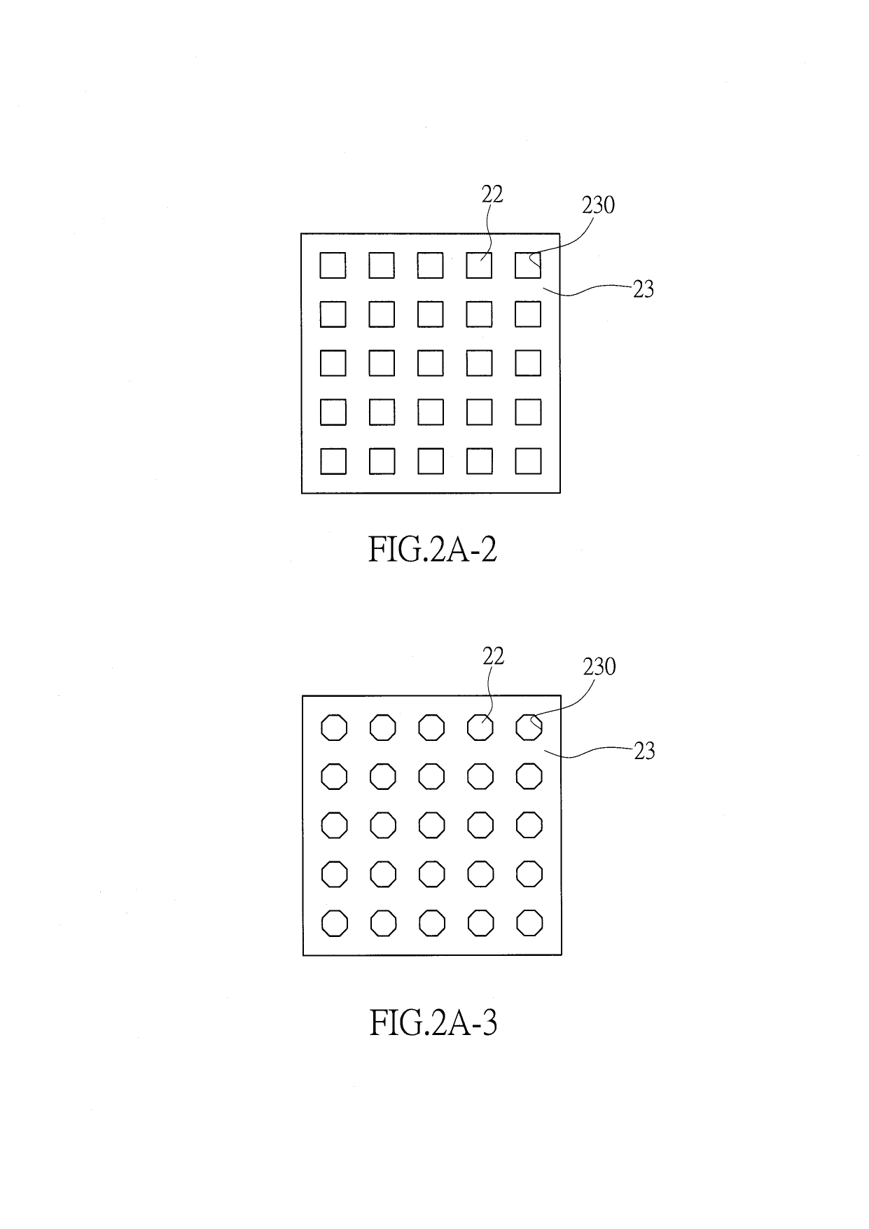

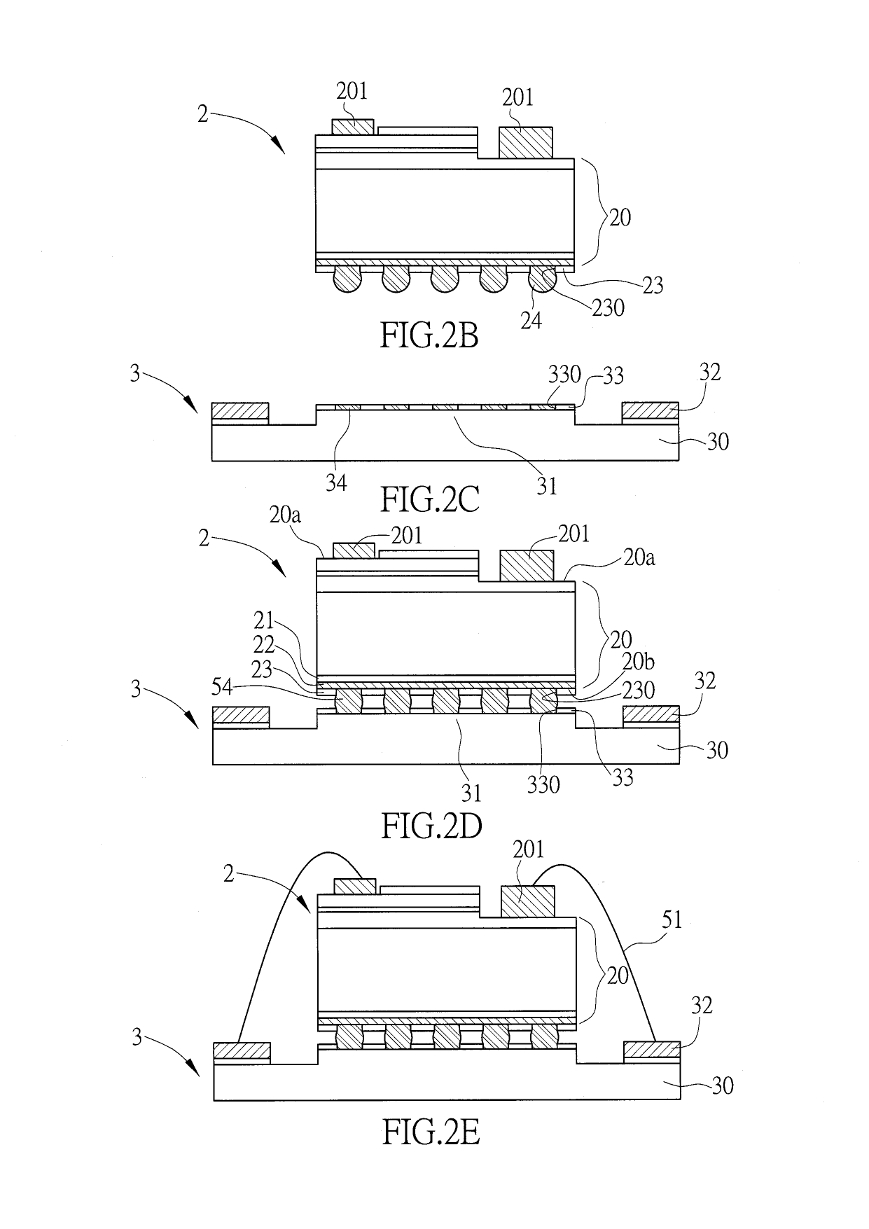

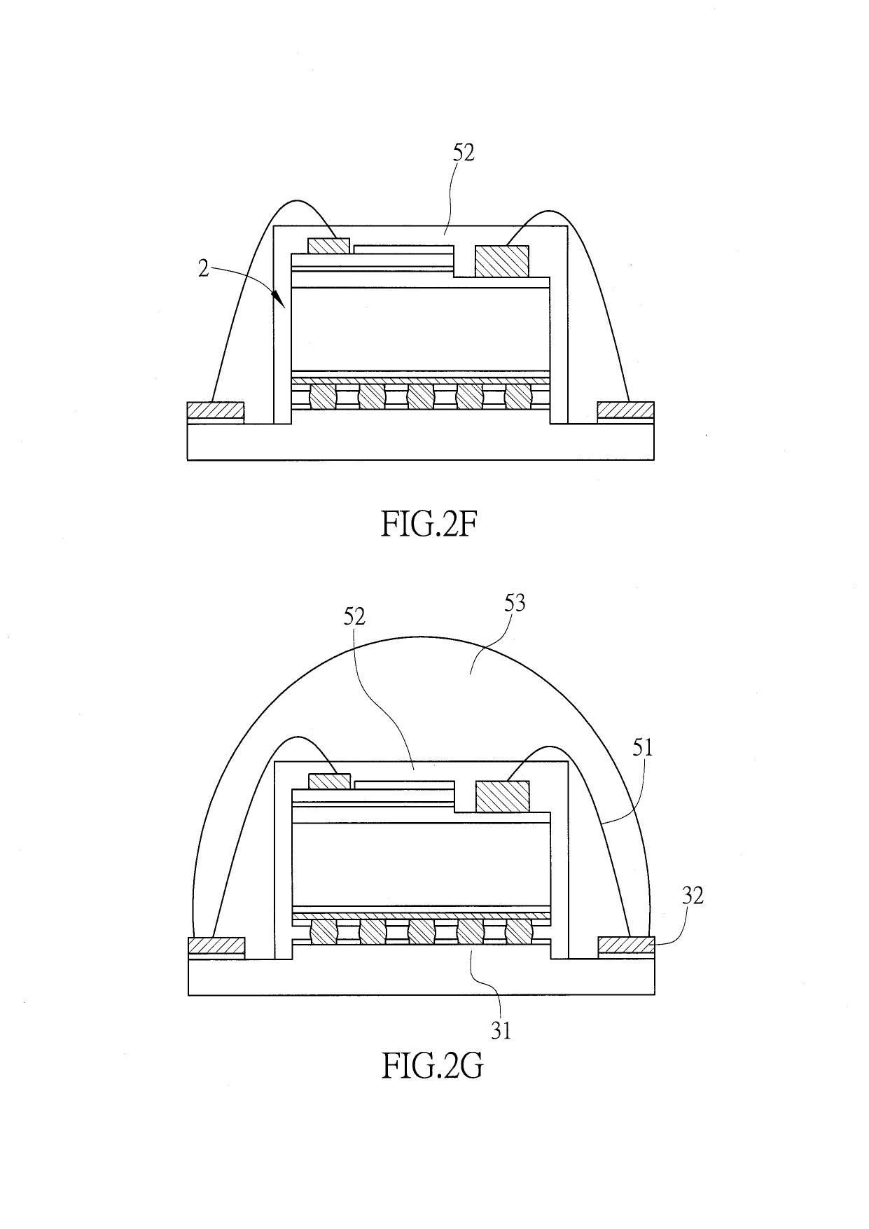

FIGS. 2A to 2G are schematic cross-sectional views showing an LED package structure and a fabrication method thereof according to a first embodiment of the present invention. Therein, FIGS. 2A-1, 2A-2 and 2A-3 are top views showing different embodiments of FIG. 2A.

Referring to FIG. 2A, an LED chip 2 is provided. The LED chip 2 has a substrate 20 having an active surface 20a and an inactive surface 20b opposite to the active surface 20a. A plurality of electrode pads 201 are formed on the active surface 20a of the substrate 20, and a reflective layer 21 and a metal layer 22 are sequentially formed on the inactive surface 20b of the substrate 20. Further, a second insulating layer 23 is formed on the inactive surface 20b of the substrate 20 and has a plurality of openings 230.

Referring to FIGS. 2A-1, 2A-2 and 2A-3, the openings 230 of the second insulating layer 23 have circular or polygonal shapes, for example, rectangular or octagonal shapes, and are arranged in an array.

Referring to FIG. 2B, a plurality of first metallic thermal conductive elements 24, such as thermal conductive metal balls, are formed in the openings 230 of the second insulating layer 23, respectively.

Referring to FIG. 2C, an LED packaging substrate 3 is provided. The LED packaging substrate 3 has a substrate 30 having a die attach pad 31 formed thereon and a plurality of bonding pads 32 formed around the periphery of the die attach pad 31. Preferably, the substrate 30 is a metal core printed circuit board (MCPCB) for enhancing the overall heat dissipating effect. A first insulating layer 33 is formed on the die attach pad 31 and has a plurality of openings 330. Further, a plurality of second metallic thermal conductive elements 34, such as thermal conductive metal layers, are formed in the openings 330 of the first insulating layer 33, respectively.

Referring to FIG. 2D, the LED chip 2 is mounted on the LED packaging substrate 3 with the openings 230 of the second insulating layer 23 corresponding in position to the openings 330 of the first insulating layer 33 such that the first metallic thermal conductive elements 24 are bonded to the second metallic thermal conductive elements 34, respectively, to thereby form a plurality of metallic thermal conductive elements 54.

Referring to FIG. 2E, a plurality of bonding wires 51 are formed to electrically connect the electrode pads 201 of the LED chip 2 and the bonding pads 32 of the packaging substrate 3.

Referring to FIG. 2F, a fluorescent layer 52 is formed to encapsulate the LED chip 2.

Referring to FIG. 2G, a transparent material 53 is formed to cover the fluorescent layer 52, the die attach pad 31, the bonding pads 32 and the bonding wires 51.

### Second Embodiment

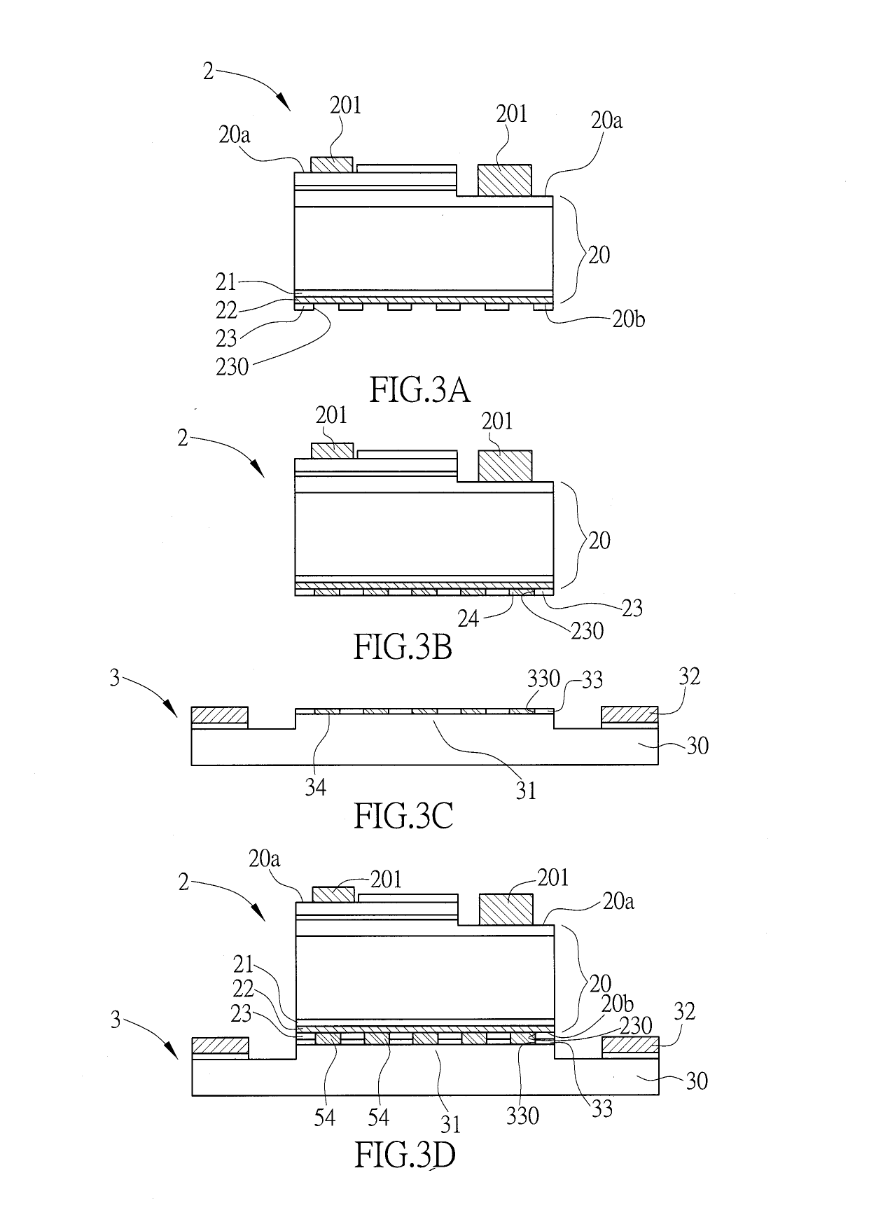

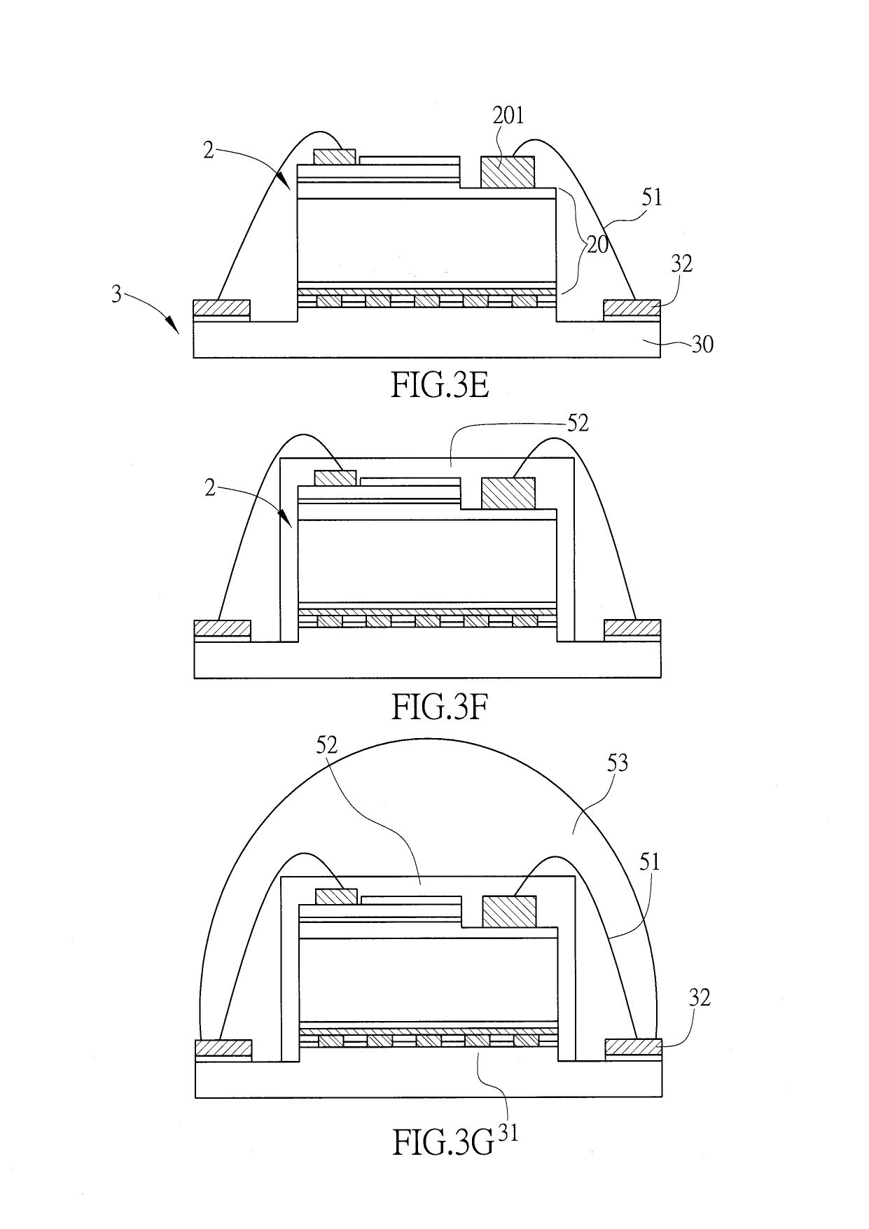

FIGS. 3A to 3G are schematic cross-sectional views showing an LED package structure and a fabrication method thereof according to a second embodiment of the present invention.

Referring to FIG. 3A, an LED chip 2 is provided. The LED chip 2 has a substrate 20 having an active surface 20a and an inactive surface 20b opposite to the active surface 20a. A plurality of electrode pads 201 are formed on the active surface 20a of the substrate 20, and a reflective layer 21 and a metal layer 22 are sequentially formed on the inactive surface 20b of the substrate 20. Further, a second insulating layer 23 is formed on the inactive surface 20b of the substrate 20 and has a plurality of openings 230.

Referring to FIG. 3B, a plurality of first metallic thermal conductive elements 24, such as thermal conductive metal layers, are formed in the openings 230 of the second insulating layer 23, respectively.

Referring to FIG. 3C, an LED packaging substrate 3 is provided. The LED packaging substrate 3 has a substrate 30 having a die attach pad 31 disposed thereon and a plurality of bonding pads 32 formed around the periphery of the die attach pad 31. A first insulating layer 33 is formed on the die attach pad 31 and has a plurality of openings 330. Further, a plurality of second metallic thermal conductive elements 34, such as thermal conductive metal layers, are formed in the openings 330 of the first insulating layer 33, respectively.

Referring to FIG. 3D, the LED chip 2 is mounted on the LED packaging substrate 3 with the openings 230 of the second insulating layer 23 corresponding in position to the openings 330 of the first insulating layer 33 such that the first metallic thermal conductive elements 24 are bonded to the second metallic thermal conductive elements 34, respectively, to thereby form a plurality of metallic thermal conductive elements 54.

Referring to FIG. 3E, a plurality of bonding wires 51 are formed to electrically connect the electrode pads 201 and the bonding pads 32.

Referring to FIG. 3F, a fluorescent layer 52 is formed to encapsulate the LED chip 2.

Referring to FIG. 3G, a transparent material 53 is formed to cover the fluorescent layer 52, the die attach pad 31, the bonding pads 32 and the bonding wires 51.

In an alternative embodiment, instead of providing both the first metallic thermal conductive elements 24 and the second metallic thermal conductive elements 34, only the first metallic thermal conductive elements 24 or the second metallic thermal conductive elements 34 may be provided. The first and second metallic thermal conductive elements 24, 34 can be thermal conductive metal layers or metal balls.

The present invention further provides an LED chip structure, which has a substrate 20 having an active surface 20a with a plurality of electrode pads 201 and an inactive surface 20b opposite to the active surface 20a; a second insulating layer 23 formed on the inactive surface 20b of the substrate 20 and having a plurality of openings 230; and a plurality of first metallic thermal conductive elements 24 formed in the openings 230 of the second insulating layer 23, respectively.

Therein, the inactive surface 20b of the substrate 20 has a reflective layer 21 so as for the second insulating layer 23 to be formed thereon. Further, the inactive surface 20b of the substrate 20 has a metal layer 22 formed between the reflective layer 21 and the second insulating layer 23, and the first metallic thermal conductive elements 24 are formed on portions of the metal layer 22 exposed through the openings 230 of the second insulating layer 23.

The first metallic thermal conductive elements 24 are thermal conductive metal layers or metal balls, which are formed in the openings 230 of the second insulating layer 23 so as to be connected to the substrate 20. The openings 230 of the second insulating layer 23 have circular or polygonal shapes and are arranged in an array.

The present invention further provides an LED packaging substrate 3, which has: a substrate 30 having a die attach pad 31; a first insulating layer 33 formed on the die attach pad 31 and having a plurality openings 330; and a plurality of second metallic thermal conductive elements 34 formed in the openings 330 of the first insulating layer 33.

Therein, the substrate 30 further has a plurality of bonding pads 32 formed around the periphery of the die attach pad 31. The second metallic thermal conductive elements 34 are thermal conductive metal layers or metal balls, which are formed in the openings 330 of the first insulating layer 33 so as to be connected to the substrate 30.

The openings 330 of the first insulating layer 33 have circular or polygonal shapes and are arranged in an array.

The present invention further provides an LED package structure. The package structure has a packaging substrate 3. Therein, the packaging substrate 3 has a substrate 30 having a die attach pad 31 formed thereon; a first insulating layer 33 formed on the die attach pad 31 and having a plurality of openings 330; and a plurality of metallic thermal conductive elements 54 formed in the openings 330 of the first insulating layer 33. The LED package structure further has an LED chip 2 mounted on the LED packaging substrate 3 through the metallic thermal conductive elements 54. The LED chip 2 has a substrate 20 having an active surface 20a with a plurality of electrode pads 201 and an inactive surface 20b opposite to the active surface 20a, and a second insulating layer 23 formed on the inactive surface 20b of the substrate 20 and having a plurality of openings 230. Therein, the LED chip 2 is mounted on the packaging substrate 3 with the openings 230 of the second insulating layer 23 corresponding in position to the openings 330 of the first insulating layer 33 such that the metallic thermal conductive elements 54 are formed in the openings 230 of the second insulating layer 23.

In the above-described LED package structure, the substrate 30 further has a plurality of bonding pads 32 formed around the periphery of the die attach pad 31, and the bonding pads 32 and the electrode pads 201 are electrically connected through a plurality of bonding wires 51. Furthermore, the package structure has a fluorescent layer 52 encapsulating the LED chip 2 and a transparent material 53 covering the fluorescent layer 52, the die attach pad 31, the bonding pads 32 and the bonding wires 51.

The openings 230 of the second insulating layer 23 and the openings 330 of the first insulating layer 33 have circular or polygonal shapes and are arranged in arrays, respectively. The metallic thermal conductive elements 54 are thermal conductive metal layers or metal balls.

Therefore, by mounting an LED chip on the die attach pad of an LED packaging substrate through a plurality of array-arranged thermal conductive elements, the present invention effectively alleviates the problem of thermal stresses induced by a mismatch in CTEs of the LED chip and the packaging substrate without greatly affecting the heat dissipating capability of the LED package structure, thus improving the reliability of the overall LED package structure.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A Light Emitting Diode (LED) chip structure, comprising:
a substrate having an active surface with a plurality of electrode pads and an inactive surface opposite to the active surface;
an insulating layer formed on the inactive surface of the substrate and having a plurality of openings; and
at least one metallic thermal conductive element formed in the openings of the insulating layer.

2. The structure of claim 1, wherein the inactive surface of the substrate further comprises a reflective layer formed on the insulating layer.

3. The structure of claim 2, wherein the inactive surface of the substrate further comprises a metal layer formed between the reflective layer and the insulating layer, and the metallic thermal conductive element is formed on portions of the metal layer exposed from the openings of the insulating layer.

4. The structure of claim 1, wherein the metallic thermal conductive element is a thermal conductive metal layer or metal ball formed in the openings of the insulating layer and electrically connected to the substrate.

5. The structure of claim 1, wherein the openings are circular or polygonal shapes and are arranged in an array.

6. An LED packaging substrate, comprising:
a substrate having a die attach pad;
an insulating layer formed on the die attach pad and having a plurality openings; and
at least one metallic thermal conductive element formed in the openings of the insulating layer.

7. The substrate of claim 6, wherein the substrate has a plurality of bonding pads formed around the die attach pad.

8. The substrate of claim 6, wherein the metallic thermal conductive element is a thermal conductive metal layer or metal ball formed in the openings of the insulating layer and electrically connected to the substrate.

9. The substrate of claim 6, wherein the openings are circular or polygonal shapes and are arranged in an array.

10. An LED package structure, comprising:
a substrate having a die attach pad;
a first insulating layer formed on the die attach pad and having a plurality of first openings;
an LED chip having an active surface with a plurality of electrode pads and an inactive surface opposite to the active surface;
a second insulating layer formed on the inactive surface of the LED chip and having a plurality of second openings; and
at least one metallic thermal conductive element formed in the first openings and the second openings.

11. The structure of claim 10, wherein the substrate further has a plurality of bonding pads formed around the die attach pad and a plurality of bonding wires are further provided for electrically connecting the electrode pads and the bonding pads.

12. The structure of claim 11, further comprising a fluorescent layer for encapsulating the LED chip.

13. The structure of claim 12, further comprising a transparent material covering the fluorescent layer, the die attach pad, the bonding pads, and the bonding wires.

14. The structure of claim 10, wherein the first openings and the second openings are circular or polygonal shapes and are arranged in arrays.

15. The structure of claim 10, wherein the LED chip is disposed on the substrate with the openings of the second insulating layer corresponding in position to the openings of the first insulating layer.

16. A fabrication method of an LED package structure, comprising the steps of:
providing a substrate having a die attach pad and a first insulating layer formed on the die attach pad, wherein the first insulating layer has a plurality of openings; and
mounting an LED chip on the substrate through at least one metallic thermal conductive element,
wherein the LED chip has an active surface with a plurality of electrode pads and an inactive surface opposite to the active surface, a second insulating layer is formed on the inactive surface of the LED chip, the second insulating layer has a plurality of second openings, and the at least one metallic thermal conductive element is formed in the first openings and the second openings.

17. The method of claim 16, wherein the LED chip has a plurality of first metallic thermal conductive elements formed in the first openings, and the substrate has at least one second metallic thermal conductive element formed in the second openings, such that when the LED chip is mounted on the substrate, the first and second metallic thermal conductive elements are bonded to each other to form the at least one metallic thermal conductive element.

18. The method of claim 16, further comprising forming a plurality of bonding wires to electrically connect the electrode pads and a plurality of bonding pads formed around the periphery of the die attach pad.

19. The method of claim 18, further comprising forming a fluorescent layer to encapsulate the LED chip.

20. The method of claim 19, further comprising forming a transparent material to cover the fluorescent layer, the die attach pad, the bonding pads, and the bonding wires.

21. The method of claim 16, wherein the first openings and the second openings are circular or polygonal shapes and are arranged in arrays, respectively.

22. The method of claim 16, wherein the at least one metallic thermal conductive element is a thermal conductive metal layer or metal ball.
